(19) United States
(12) Patent Application Publication
(10) Pub. No.: US 2026/0188604 A1
(43) Pub. Date: Jul. 2, 2026

(54) SEMICONDUCTOR MANUFACTURING APPARATUS INCLUDING REFLECTOR

(71) Applicant: SAMSUNG ELECTRONICS CO., LTD., Suwon-si (KR)

(72) Inventor: CHEOL KIM, Suwon-si (KR)

(73) Assignee: SAMSUNG ELECTRONICS CO., LTD., Suwon-si (KR)

(21) Appl. No.: 19/431,350

(22) Filed: Dec. 23, 2025

(30) Foreign Application Priority Data
Dec. 27, 2024 (KR) 10-2024-0198727

(51) Int. Cl. H01J 37/147; H01J 37/08; H01J 37/20; H10P 72/00

(52) U.S. Cl. CPC H01J 37/147; H01J 37/08; H01J 37/20; H10P 72/0421; H01J 2237/0041

(57) ABSTRACT

A semiconductor manufacturing apparatus may include: a first chamber including a first internal space; an ion generator configured to generate ions within the first internal space; a second chamber including a second internal space, the second internal space communicatively connected to the first internal space; a beam generator between the first internal space and the second internal space and configured to convert the ions into ion beams; a chuck within the second chamber; and a reflector within the second chamber, the reflector including a reflective surface that is curved, and the reflector configured to reflect the ion beams toward the chuck.

### CROSS-REFERENCE TO RELATED APPLICATION

This U.S. non-provisional application claims priority under 35 USC § 119 to Korean Patent Application No. 10-2024-0198727, filed on Dec. 27, 2024, in the Korean Intellectual Property Office, the disclosure of which is herein incorporated by reference in its entirety.

### BACKGROUND

### 1. Field

Some embodiments of the present disclosure relate to a semiconductor manufacturing apparatus and a method of manufacturing a semiconductor device.

### 2. Brief Description of Related Art

A semiconductor device may be manufactured through a series of semiconductor manufacturing processes, including photolithography, etching, ion implantation, or the like. Recent advancements in semiconductor manufacturing have introduced ion beam etching (IBE) as an innovative method. In such an etching process, a substrate may be etched by a semiconductor manufacturing apparatus such as, for example, an ion beam etching apparatus.

### SUMMARY

According to some embodiments of the present disclosure, a semiconductor manufacturing apparatus configured to provide neutral beams, converted using a reflector having a curved reflective surface, to a substrate may be provided.

According to some embodiments of the present disclosure, a semiconductor manufacturing apparatus may include: a first chamber including a first internal space; an ion generator configured to generate ions within the first internal space; a second chamber including a second internal space, the second internal space communicatively connected to the first internal space; a beam generator between the first internal space and the second internal space and configured to convert the ions into ion beams; a chuck within the second chamber; and a reflector within the second chamber, the reflector including a reflective surface that is curved, and the reflector configured to reflect the ion beams toward the chuck.

According to some embodiments of the present disclosure, a semiconductor manufacturing apparatus may include: a first chamber including a first internal space; an ion generator configured to generate ions within the first internal space; a second chamber including a second internal space, the second internal space communicatively connected to the first internal space; a beam generator between the first internal space and the second internal space and configured to convert the ions into ion beams; a chuck within the second chamber; and a reflector within the second chamber, the reflector including a reflective surface that is curved, and the reflector configured to reflect the ion beams toward the chuck, wherein the reflective surface of the reflector is configured to reflect the ion beams in a first direction at different angles, the different angles being in a cross-sectional view of the semiconductor manufacturing apparatus taken along a plane that is parallel to the first direction and a second direction that crosses the first direction.

According to some embodiments of the present disclosure, a semiconductor manufacturing apparatus may include: a first chamber including a first internal space; an ion generator configured to generate ions within the first internal space; a second chamber including a second internal space, the second internal space communicatively connected to the first internal space; a beam generator between the first internal space and the second internal space and configured to convert the ions into ion beams; a chuck within the second chamber and configured to support a substrate; and a reflector within the second chamber, the reflector including a plurality of sub-reflectors that include a reflective surface that is curved, and the plurality of sub-reflectors configured to reflect the ion beams toward the chuck

### BRIEF DESCRIPTION OF DRAWINGS

FIG. 1 is a cross-sectional view of a semiconductor manufacturing apparatus according to one or more embodiments.

FIG. 2 is a cross-sectional view illustrating an etching method of a semiconductor manufacturing apparatus according to one or more embodiments.

FIG. 3 is a cross-sectional view taken along a line I-I of FIG. 2.

FIG. 4 is a cross-sectional view of a semiconductor manufacturing apparatus according to one or more embodiments.

FIG. 5 is a cross-sectional view of a semiconductor manufacturing apparatus according to one or more embodiments.

FIG. 6 is a plan view of a semiconductor manufacturing apparatus according to one or more embodiments.

FIG. 7 is a plan view of a semiconductor manufacturing apparatus according to one or more embodiments.

FIG. 8 is a cross-sectional view of a semiconductor manufacturing apparatus according to one or more embodiments.

### DETAILED DESCRIPTION

Hereinafter, non-limiting example embodiments of the present disclosure will be described with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

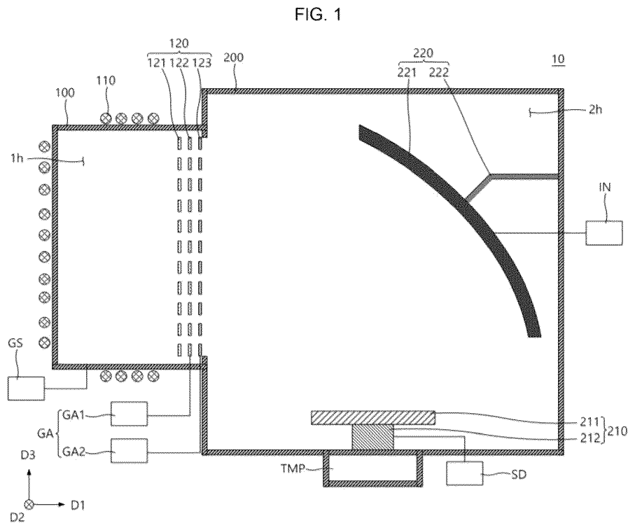

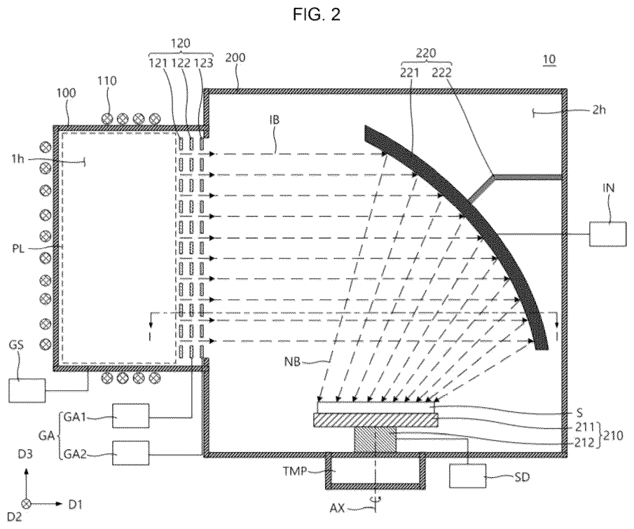

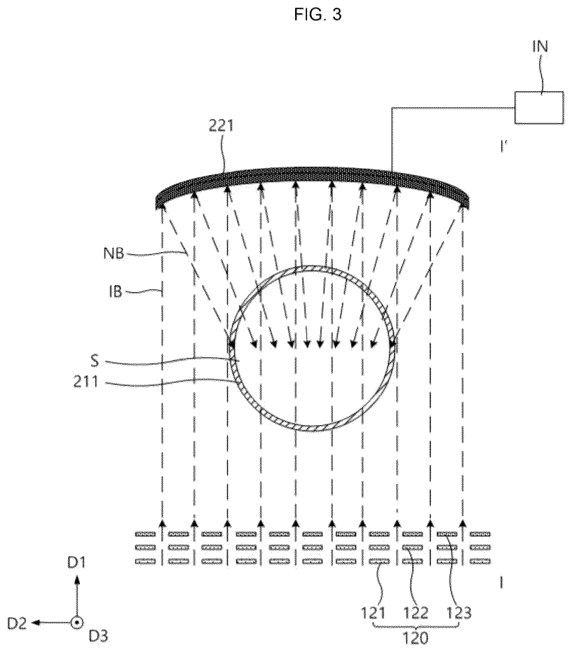

FIG. 1 is a cross-sectional view of a semiconductor manufacturing apparatus according to one or more embodiments. FIG. 2 is a cross-sectional view illustrating an etching method of a semiconductor manufacturing apparatus according to one or more embodiments. FIG. 3 is a cross-sectional view taken along a line I-I of FIG. 2. In one or more embodiments, the semiconductor manufacturing apparatus may be an etching apparatus for etching a substrate.

Hereinafter, non-limiting example embodiments of the present disclosure are described with reference to a first direction D1, a second direction D2 intersecting (e.g., perpendicular to) the first direction D1, and a third direction D3 intersecting (e.g., perpendicular to) each of the first direction D1 and the second direction D2.

Referring to FIG. 1, a semiconductor manufacturing apparatus 10 according to one or more embodiments may include a first chamber 100 and a second chamber 200. The first chamber 100 may include an ion generator 110, a beam generator 120, a grid actuator GA, and a gas supplier GS. The second chamber 200 may include a substrate support 210, a chuck actuator SD, a turbomolecular pump TMP, a reflector system 220, and an ion neutralizer IN.

The first chamber 100 may include a bottom portion, a ceiling portion, and a wall portion, which may define a first internal space 1h. The first chamber 100 may be provided with an opening penetrating through the wall portion of the first chamber 100. Materials within the first internal space 1h may be discharged to the outside of the first chamber 100 through the opening. In one or more embodiments, the first chamber 100 may include a cover to open and close the opening.

The ion generator 110 may be coupled to the first chamber 100. The ion generator 110 may have the form of a radio frequency (RF) coil, as illustrated, and may include RF coils. The ion generator 110 may be provided along an outer surface of the first chamber 100. However, the ion generator 110 is not limited thereto and may include other types of devices besides RF coils. In one or more embodiments, the ion generator 110 may generate an electric field and/or a magnetic field within the first internal space 1h. Accordingly, at least a portion of the gases in the first internal space 1h may be converted into plasma and generate ions.

In one or more embodiments, the generated ions may be inert ions. For example, the ions may be argon (Ar) ions, neon (Ne) ions, helium (He) ions, krypton (Kr) ions, xenon (Xe) ions, or radon (Rn) ions.

The beam generator 120 may be coupled to one side of the first chamber 100 and provided between the first chamber 100 and the second chamber 200. The beam generator 120 may have a through-hole. The beam generator 120 may convert ions, generated by the ion generator 110, into ion beams IB (see FIG. 2). The ion beams IB may include positive ions or negative ions under the control of the beam generator 120. In one or more embodiments, the beam generator 120 may include at least one grid. For example, the beam generator 120 may include a first grid 121, a second grid 122, and a third grid 123.

The grids (e.g., the first grid 121, the second grid 122, and the third grid 123) may be provided in the first chamber 100 and extract ions from the plasma in the first internal space 1h. In one or more embodiments, each of the grids (e.g., the first grid 121, the second grid 122, and the third grid 123) may have a plate shape extending perpendicular to the first direction D1. For example, each of the grids (e.g., the first grid 121, the second grid 122, and the third grid 123) may have a plate shape extending in the second direction D2 and/or the third direction D3. For example, each of the grids (e.g., the first grid 121, the second grid 122, and the third grid 123) may have a disk shape.

The grids (e.g., the first grid 121, the second grid 122, and the third grid 123) may be arranged in the first direction D1 and disposed to overlap with each other. The first grid 121 may be grounded. For example, the first grid 121 may be a ground grid. The second grid 122 may be a screen grid. The third grid 123 may be an acceleration grid. Each of the grids (e.g., the first grid 121, the second grid 122, and the third grid 123) may be formed of at least one from among stainless steel (SUS), carbon graphite, copper (Cu), or aluminum (Al), but embodiments are not limited thereto. Although the grids (e.g., the first grid 121, the second grid 122, and the third grid 123) have been illustrated and described as including three grids, embodiments are not limited thereto, and four or more grids or two grids may be provided.

The grid actuator GA may move at least one of the grids (e.g., the first grid 121, the second grid 122, and the third grid 123). For example, the grid actuator GA may move one or more of the grids (e.g., the first grid 121, the second grid 122, and the third grid 123) and may also move any remaining grids. For example, the grid actuator GA may move the second grid 122 relative to the first grid 121 in the first direction D1 and/or the third direction D3.

In addition, the grid actuator GA may rotate the second grid 122 about an axis parallel to the first direction D1. In one or more embodiments, a plurality of grid actuators GA may be provided. For example, the grid actuators GA may include a first grid actuator GA1 and a second grid actuator GA2.

The first grid actuator GA1 may move the second grid 122. In one or more embodiments, the first grid actuator GA1 may move the second grid 122 in at least one from among the first to third directions D1, D2, and D3 while the first grid 121 is fixed. In addition, the first grid actuator GA1 may rotate the second grid 122 about an axis parallel to the first direction D1 while the first grid 121 is fixed. To this end, the first grid actuator GA1 may include a motor, a hydraulic device, or the like.

In addition, the first grid actuator GA1 may include a mechanism to transfer generated power to the second grid 122. However, embodiments are not limited thereto, and the first grid actuator GA1 may include other types of configurations to move the second grid 122.

The second grid actuator GA2 may move the third grid 123. In one or more embodiments, the second grid actuator GA2 may move the third grid 123 in at least one from among the first to third directions D1, D2, and D3 while the first grid 121 is fixed.

In addition, the second grid actuator GA2 may rotate the third grid 123 about an axis parallel to the first direction D1 while the first grid 121 is fixed. To this end, the second grid actuator GA2 may include a motor, a hydraulic device, or the like. In addition, the second grid actuator GA2 may include a mechanism to transfer generated power to the third grid 123. However, embodiments are not limited thereto, and the second grid actuator GA2 may include other types of configurations to move the third grid 123.

The gas supplier GS may supply gas to the first internal space 1h. In one or more embodiments, the gas supplier GS may include a gas tank, a compressor, a pipe, a valve, or the like. According to some embodiments, the gas supplier GS may supply an inert gas. For example, the gas supplier GS may supply argon, neon, helium, krypton, xenon, or radon.

The second chamber 200 may include a bottom portion, a ceiling portion, and a wall portion, which may define a second internal space 2h. The second chamber 200 may be provided with an opening penetrating through the wall portion of the second chamber 200. The second chamber 200 may be coupled to one side of the first chamber 100, but embodiments are not limited thereto.

In one or more embodiments, the first chamber 100 and the second chamber 200 may be spaced apart from each other at a certain distance. The second internal space 2h may be communicatively connected to the first internal space 1h. The first internal space 1h may be communicatively connected to the second internal space 2h through the beam generator 120. In one or more embodiments, the second internal space 2h may be maintained at a substantial vacuum during an ion beam etching process.

The substrate support 210 may be provided within the second chamber 200 and spaced apart from the beam generator 120. The substrate support 210 may fix a substrate S (see FIG. 2) at a specific location within the second internal space 2h. The substrate support 210 may include a chuck 211 and a chuck rotator 212.

The chuck 211 may support the substrate S. In one or more embodiments, the chuck 211 may fix the substrate S in various ways. For example, the chuck 211 may be an electrostatic chuck (ESC) and/or a vacuum chuck. However, embodiments are not limited thereto, and the substrate S may be disposed on the chuck 211 without additional fixing force.

The chuck rotator 212 may rotate the chuck 211. In one or more embodiments, the chuck rotator 212 may include an actuator such as a motor.

The chuck actuator SD may rotate the substrate support 210. In one or more embodiments, the chuck actuator SD may provide rotational power to the chuck rotator 212, enabling the chuck rotator 212 to rotate the chuck 211.

The turbomolecular pump TMP may be connected to the second internal space 2h. In one or more embodiments, the turbomolecular pump TMP may maintain the second internal space 2h at a substantial vacuum during the ion beam etching process.

The reflector system 220 may be spaced apart from the beam generator 120 and the substrate support 210. For example, the reflector system 220 may be spaced apart from the beam generator 120 in the first direction D1. For example, the reflector system 220 may be spaced apart from the substrate support 210 in the first direction D1 and the third direction D3. In one or more embodiments, the reflector 221 is movable, rotatable, and tiltable. The reflector system 220 may include a reflector 221 and a reflector actuator 222.

The reflector 221 may be provided within the second chamber 200 and may reflect ion beams IB (see FIG. 2), provided from the beam generator 120, toward the chuck 211. In one or more embodiments, the reflector 221 may have a reflective surface that is a curved surface, and the reflective surface may be concave. A portion of the reflector 221 may be etched due to the incident ion beams IB. Accordingly, the reflector 221 may have a minimum thickness set to ensure appropriate durability, and the minimum thickness may be defined as a condition that all thicknesses of the reflector 221 should satisfy. In one or more embodiments, the minimum thickness may be 20 mm, but embodiments are not limited thereto.

Referring to FIG. 2, the reflector 221 may have a reflective surface that is a curved surface with respect to cross-sections parallel to the first direction D1 and the third direction D3, and the reflective surface may convert incident ion beams IB into neutral beams NB and reflect the converted neutral beams NB at different angles. For example, in the cross-sections parallel to the first direction D1 and the third direction D3, a slope of a tangent at one point on the reflective surface may be different from a slope of a tangent at another point on the reflective surface.

Referring to FIG. 3, the reflector 221 may have a reflective surface that is a curved surface with respect to cross-sections parallel to the first direction D1 and the second direction D2, and the reflective surface may convert incident ion beams IB into neutral beams NB and reflect at least a portion of the converted neutral beams NB at different angles. The reflective surface of the reflector 221 in cross-sections parallel to the first direction D1 and the second direction D2 may be symmetrical with respect to the center of the reflector 221. Accordingly, the neutral beams NB reflected in the cross-sections parallel to the first direction D1 and the second direction D2 may be reflected at the same angle when they are reflected at the same distance from the center of the reflector 221.

In one or more embodiments, the reflector 221 includes a reflective surface that is a curved surface, and an area of the reflective surface of the reflector 221 may be different from an area of the ion beams IB and an area of the substrate S (e.g., an area of an upper surface of the substrate S). For example, the area of the reflective surface of the reflector 221 may be larger than the area of the substrate S. For example, the area of the reflective surface of the reflector 221 may be larger than an area in which the ion beams IB are provided. For example, the area of the reflective surface of the reflector 221 may be larger than an area of an upper surface of the chuck 211. Since the area of the reflective surface of the reflector 221 may be larger than the area in which the ion beams IB are provided, the reflector 221 may reflect all of the ion beams IB emitted from the beam generator 120. Although the area of the reflective surface of the reflector 221 may be larger than the area of the substrate S, the reflective surface includes a curved surface, so that the reflector 221 may provide all of the reflected ion beams IB or all of the converted and reflected neutral beams NB to the substrate S. Accordingly, even when the area of the incident ion beams IB is larger than the area of the substrate S, the reflector 221 may provide all of the ion beams IB or all of the neutral beams NB converted from the ion beams IB to the substrate S.

In one or more embodiments, the reflector 221 may include conductive materials and/or materials configured to reflect ion beams IB. For example, the reflector 221 may be formed of at least one from among metal-based materials, undoped silicon (Si), doped silicon, aluminum (Al), molybdenum (Mo), ruthenium (Ru), carbon compounds, tantalum nitride (TaN), and titanium nitride (TiN). The reflector 221 may be tilted at a predetermined angle with respect to the direction of the ion beams IB passing through the grids (e.g., the first grid 121, the second grid 122, and the third grid 123).

In one or more embodiments, the reflector 221 may include a plurality of stacked layers. Each of the stacked layers may be formed of at least one from among metal-based materials, undoped silicon (Si), doped silicon, aluminum (Al), molybdenum (Mo), ruthenium (Ru), carbon compounds, tantalum nitride (TaN), and titanium nitride (TiN), and adjacent layers among the stacked layers may be formed of different materials from each other.

In one or more embodiments, the reflector 221 may include a plurality of materials. The plurality of materials may be disposed within the reflector 221 to avoid overlap with each other.

The reflector actuator 222 may support the reflector 221, and the reflector actuator 222 may fix the reflector 221 at a specific location within the second internal space 2h. The coupling between the reflector 221 and the reflector actuator 222 may be achieved by a coupling means such as a bolt, but embodiments are not limited thereto. In one or more embodiments, the reflector actuator 222 may rotate in place, move freely within the second internal space 2h, and be tilted to adjust an angle of the reflective surface of the reflector 221.

The ion neutralizer IN may be electrically connected to the reflector 221 and may neutralize the ion beams IB that contact the reflector 221. The ion neutralizer IN may provide a polarity, opposite to the polarity of the ion beams IB, to the reflector 221, and the ion beams IB reflected by the reflector 221 may be neutralized by the opposite polarity.

Referring to FIGS. 2 and 3, the ion beam etching method may include placing a substrate S in a semiconductor manufacturing apparatus 10. In one or more embodiments, the substrate S may be placed on the chuck 211. In addition, the ion beam etching method may include irradiating ion beams IB, generated from the beam generator 120, to the reflector 221.

The gas supplied to the first internal space 1h by the gas supplier GS may be converted into plasma PL by the ion generator 110. Accordingly, the plasma PL may be generated within the first chamber 100. A portion of the plasma PL in the first chamber 100 may be extracted into the second internal space 2h through the grids (e.g., the first grid 121, the second grid 122, and the third grid 123). As a result, ion beams IB may be generated. The ion beams IB may be irradiated to the reflector 221.

The ions of the ion beams IB irradiated onto the reflector 221 may be positive ions or negative ions. For example, a case in which the ions of the ion beams IB are positive ions is as follows.

The first grid 121 may be applied with a reference potential, which may be selected from a ground potential or other potentials. In one or more embodiments, the reference potential may be the ground potential.

The second grid 122 may be applied with a potential lower than the reference potential. As described above, when the potential of the first grid 121 is the reference potential, the potential of the second grid 122 may be a negative potential. Accordingly, positive ions in the plasma PL within the first internal space 1h may move from the first grid 121 toward the second grid 122 due to a difference between the reference potential of the first grid 121 and the negative potential of the second grid 122.

The third grid 123 may be applied with a potential lower than both the reference potential and the potential of the second grid 122. Accordingly, the positive ions moving to the second grid 122 may move from the second grid 122 toward the third grid 123 due to a difference between the potential of the second grid 122 and the potential of the third grid 123. Thus, the ion beams IB including the positive ions may be emitted.

In addition, a case in which the ions of the ion beams IB are negative ions is as follows. The first grid 121 may be applied with a reference potential, which may be selected from a ground potential or other potentials. In one or more embodiments, the reference potential may be the ground potential.

The second grid 122 may be applied with a potential higher than the reference potential. As described above, when the potential of the first grid 121 is the reference potential, the potential of the second grid 122 may be a positive potential. Accordingly, negative ions in the plasma PL within the first internal space 1h may move from the first grid 121 toward the second grid 122 due to the difference between the reference potential of the first grid 121 and the positive potential of the second grid 122.

The third grid 123 may be applied with a potential higher than both the reference potential and the potential of the second grid 122. Accordingly, the negative ions moving to the second grid 122 may move from the second grid 122 toward the third grid 123 due to a difference between the potential of the second grid 122 and the potential of the third grid 123. Accordingly, ion beams IB including negative ions may be emitted.

The ion beams IB irradiated to the reflector 221 may be reflected by the reflector 221. Since the reflector 221 is applied with a voltage of opposite polarity to the polarity of the ions in the ion beams IB by the ion neutralizer IN, the ion beams IB irradiated to the reflector 221 may lose or gain electrons during collision with the reflector 221 to be converted into neutral beams NB.

In one or more embodiments, the ion beams IB may be positive or negative ions, so that the ion neutralizer IN may apply a voltage of different polarity depending on the polarity of the ions in the ion beams IB. For example, when the ions in the ion beams IB are positive ions, the ion neutralizer IN may apply a negative voltage and may be grounded. For example, when the ions in the ion beams IB are negative ions, the ion neutralizer IN may apply a positive voltage and may be grounded.

The neutral beams NB may include electrically neutral particles and may not be affected by an electric field. The neutral beams NB may be provided to the substrate S and may perform a process of etching the substrate S.

Referring to FIG. 2, the ion beam etching method may further include rotating the substrate S. Rotating the substrate S may be performed substantially simultaneously with irradiating the ion beams IB toward the reflector 221. The substrate S may rotate about a first axis AX. For example, the substrate S may rotate about the axis AX by the chuck actuator SD and/or the chuck rotator 212.

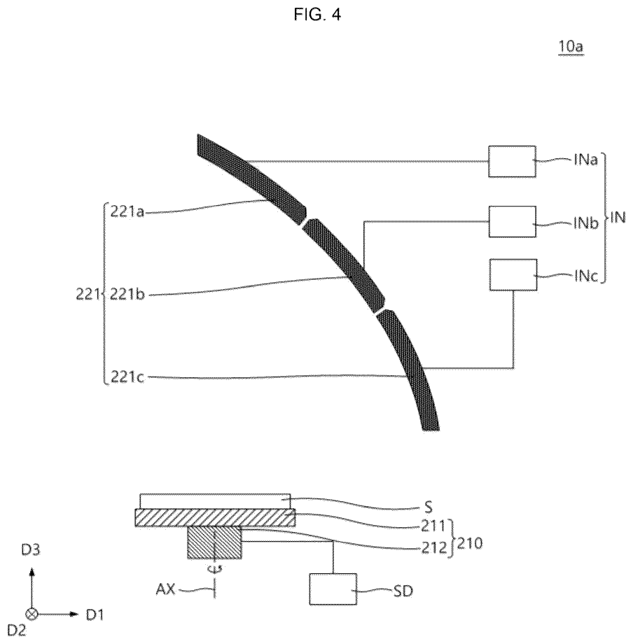

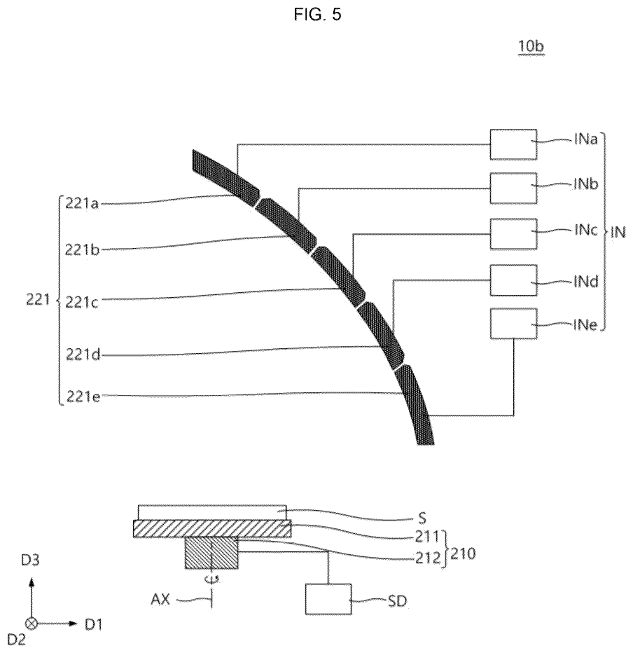

FIGS. 4 and 5 are cross-sectional views of a semiconductor manufacturing apparatus according to one or more embodiments.

Referring to FIGS. 4 and 5, a reflector 221 according to one or more embodiments may include a plurality of sub-reflectors 221a, 221b, 221c, 221d, 221e, or the like. The sub-reflectors 221a to 221e may be defined as individual pieces formed by dividing the reflector 221. The sub-reflectors 221a to 221e of FIGS. 4 and 5 may be formed by cutting specific points of the reflector 221 in a second direction D2. In one or more embodiments, the sub-reflectors 221a to 221e may be spaced apart from each other as illustrated in FIGS. 4 and 5, but embodiments are not limited thereto. Accordingly, the sub-reflectors 221a to 221e may be consecutively disposed in partial contact with each other without any gaps.

The sub-reflectors 221a to 221c in FIG. 4 are illustrated as three sub-reflectors and the sub-reflectors 221a to 221e in FIG. 5 are illustrated as five sub-reflectors, but embodiments are not limited thereto. The reflector 221 according to one or more embodiment may include two or four sub-reflectors, or six or more sub-reflectors.

In one or more embodiments, the sub-reflectors 221a to 221e may be connected to ion neutralizers INa to INe, respectively. The ion neutralizers INa to INe may be electrically connected to the sub-reflectors 221a to 221e to apply voltages, respectively. Each of the neutralizers INa to INe may neutralize the ion beams incident on each of the electrically connected sub-reflectors 221a to 221e by applying a voltage of a polarity opposite to a polarity of the ion beams to the corresponding sub-reflectors 221a to 221e. Each of the ion neutralizers INa to INe may apply the same or a similar level of voltage, or different voltages.

In one or more embodiments, the reflectors 221a to 221e may be coupled to reflector actuators (e.g., reflector actuators 222 of FIG. 1), respectively. The reflector actuators may be coupled to the sub-reflector 221a to 221e to adjust the position, rotation, or tilt of each of the sub-reflector 221a to 221e, respectively. For example, the reflector actuators may move away from each other, causing the sub-reflectors 221a to 221e to be spaced apart from each other. For example, the reflector actuators may move closer to each other, causing the sub-reflectors 221a to 221e to contact each other. For example, the rotation of the reflector actuators may lead to the rotation of the sub-reflectors 221a to 221e. For example, the reflector actuators may move while fixing the position of one side of the sub-reflectors 221a to 221e to control the tilt of the reflective surface of each sub-reflector 221a to 221e. Accordingly, the tilt of the surface of each of the sub-reflector 221a to 221e may vary individually.

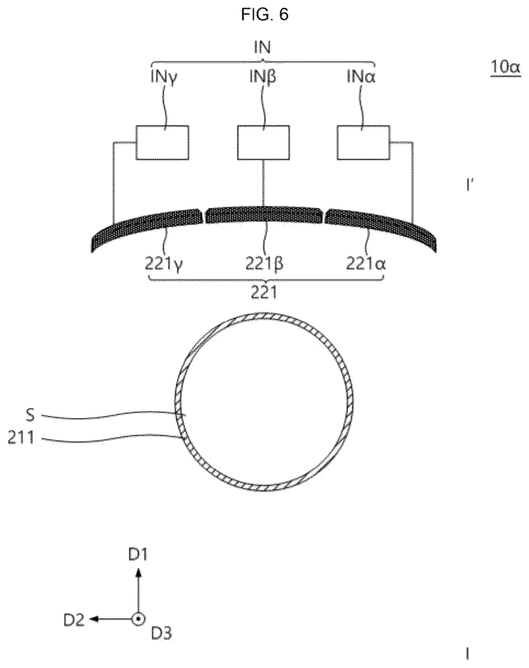

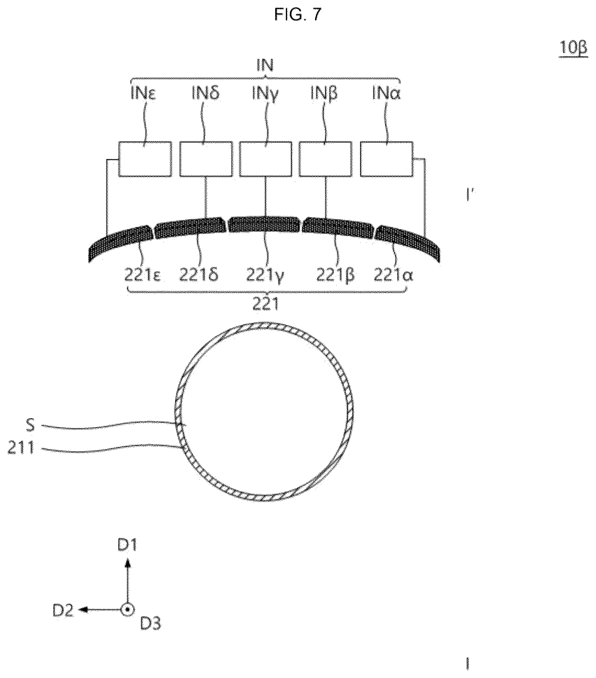

FIGS. 6 and 7 are plan views of a semiconductor manufacturing apparatus according to one or more embodiments.

Referring to FIGS. 6 and 7, a reflector 221 according to one or more embodiments may include a plurality of sub-reflectors 221α, 221β, 221γ, 221δ, 221ε, or the like. The sub-reflectors 221α to 221ε may be defined as individual pieces formed by dividing the reflector 221. The sub-reflectors 221α to 221ε in FIGS. 6 and 7 may be formed by cutting specific points of the reflector 221 in a third direction D3. In one or more embodiments, the sub-reflectors 221α to 221ε may be spaced apart from each other as illustrated in FIGS. 6 and 7, but embodiments are not limited thereto. Accordingly, the sub-reflectors 221α to 221ε may be consecutively disposed in partial contact with each other without any gaps.

The sub-reflectors 221α to 221γ in FIG. 6 are illustrated as three sub-reflectors and the sub-reflectors 221α to 221ε in FIG. 7 are illustrated as five sub-reflectors, but embodiments are not limited thereto. The reflector 221 according to one or more embodiments may include two or four sub-reflectors, or six or more sub-reflectors.

In one or more embodiments, the sub-reflectors 221α to 221ε may be connected to ion neutralizers INα to INε, respectively. The ion neutralizers INα to INε may be electrically connected to the sub-reflector 221α to 221ε to apply voltages, respectively. Each of the ion neutralizers INα to INε may neutralize the ion beams incident on each of the electrically connected sub-reflectors 221α to 221ε by applying a voltage of polarity opposite to a polarity of the ion beams to the corresponding sub-reflectors 221α to 221ε. Each of the ion neutralizers INα to INε may apply the same or a similar level of voltage, or different voltages.

In one or more embodiments, the reflectors 221α to 221ε may be coupled to reflector actuators (e.g., reflector actuators 222 of FIG. 1), respectively. The reflector actuators may be coupled to the sub-reflector 221α to 221ε to adjust the position, rotation, or tilt of each of the sub-reflector 221α to 221ε, respectively. For example, the reflector actuators may move away from each other, causing the sub-reflectors 221α to 221ε to be spaced apart from each other. For example, the reflector actuators may move closer to each other, causing the sub-reflectors 221α to 221ε to contact each other. For example, the rotation of the reflector actuators may lead to the rotation of the sub-reflectors 221α to 221ε. For example, the reflector actuators may move while fixing the position of one side of the sub-reflectors 221α to 221ε to control the tilt of the reflective surface of each sub-reflector 221α to 221ε. Accordingly, the tilt of the surface of each of the sub-reflector 221α to 221ε may vary individually.

Referring to FIGS. 4 to 7, sub-reflectors according to one or more embodiments may be formed by cutting specific points of the reflector 221 in the second direction D2 and the third direction D3. Referring to FIGS. 4 and 6, the sub-reflectors may be cut into three pieces in the second direction D2 and three pieces in the third direction D3. Accordingly, a total of nine sub-reflectors may be formed. Referring to FIGS. 5 and 7, the sub-reflectors may be cut into five pieces in the second direction D2 and five pieces in the third direction D3. Accordingly, a total of 25 sub-reflectors may be formed. Since embodiments of the present disclosure may be variously modified, the number of sub-reflectors formed by cutting the reflector 221 in the second direction D2 and the third direction D3 is not limited.

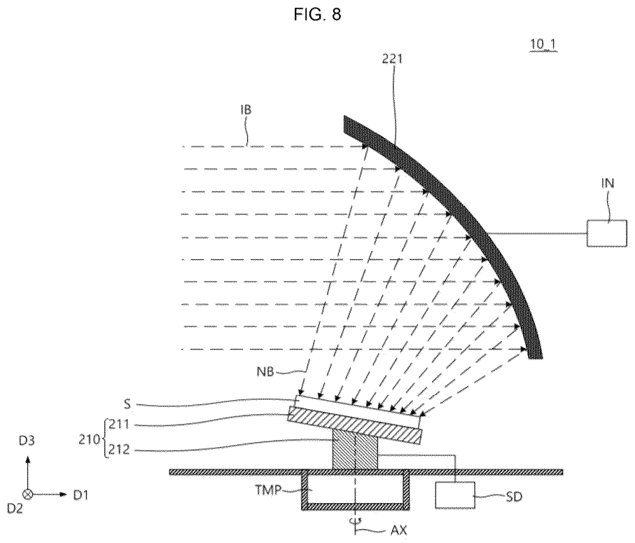

FIG. 8 is a cross-sectional view of a semiconductor manufacturing apparatus according to one or more embodiments.

Referring to FIG. 8, a chuck 211 according to one or more embodiments may be disposed to be inclined. A substrate S fixed to the chuck 211 may also be disposed to be inclined, and incident angles of ion beams IB or neutral beams NB reaching the substrate S may be adjusted. In addition, as described above, a chuck rotator 212 may rotate about an axis AX, so that the uniformity of etching applied to the substrate S may be improved.

According to some embodiments of the present disclosure, a method of manufacturing a semiconductor device may be provided. The method may include: generating, by an ion generator, ions within a first internal space of a first chamber; converting, by a beam generator, the ions into ion beams, the beam generator being between the first internal space and a second internal space of a second chamber, the second internal space communicatively connected to the first internal space; and reflecting, by a reflector within the second chamber, the ion beams towards a chuck within the second chamber, the reflector including a reflective surface that is curved.

According to some embodiments of the present disclosure, the method may further include neutralizing, by an ion neutralizer connected to the reflector, the ion beams.

According to some embodiments of the present disclosure, the ion beams include positive ions, and the ion neutralizer neutralizes the ion beams by providing electrons to the ion beams.

According to some embodiments of the present disclosure, wherein the reflecting includes reflecting the ion beams towards a substrate that is supported by the chuck, and an area of the reflective surface of the chuck is larger than an area of an upper surface of the substrate.

According to some embodiments of the present disclosure, the semiconductor manufacturing apparatus 10 may further include a controller configured to control the semiconductor manufacturing apparatus 10 to perform its functions (e.g., the functions described in the present disclosure). For example, the controller may control at least one from among the ion generator 110, the beam generator 120, the grid actuator(s) GA, the gas supplier GS, the chuck rotator 212, the chuck actuator SD, the turbomolecular pump TMP, the reflector actuator(s) 222, and the ion neutralizer(s) IN to perform their respective functions.

According to some embodiments of the present disclosure, the controller may include at least one processor and a memory storing computer instructions. The computer instructions, when executed by the at least one processor, may be configured to cause the controller to performs its functions.

As described above, converted neutral beams may be provided, during an etching process, to a substrate using a reflector having a curved reflective surface. As a result, substrate damage caused by ion beams may be reduced, and the density of the beams may be increased.

As set forth above, according to one or more embodiments, converted neutral beams may be provided, during an etching process, to a substrate using a reflector having a curved reflective surface. As a result, substrate damage caused by ion beams may be reduced, and the density of the beams may be increased.

While non-limiting example embodiments of the present disclosure have been described above with reference to the accompanying drawings, it will be apparent to those skilled in the art that modifications and variations could be made without departing from the scope of the present disclosure.

What is claimed is:

1. A semiconductor manufacturing apparatus comprising:
a first chamber including a first internal space;
an ion generator configured to generate ions within the first internal space;
a second chamber including a second internal space, the second internal space communicatively connected to the first internal space;
a beam generator between the first internal space and the second internal space and configured to convert the ions into ion beams;
a chuck within the second chamber; and
a reflector within the second chamber, the reflector comprising a reflective surface that is curved, and the reflector configured to reflect the ion beams toward the chuck.

2. The semiconductor manufacturing apparatus of claim 1, further comprising:
an ion neutralizer connected to the reflector and configured to neutralize the ion beams.

3. The semiconductor manufacturing apparatus of claim 2, wherein
the beam generator is configured to cause the ion beams to include positive ions, and
the ion neutralizer is configured to provide electrons to the ion beams.

4. The semiconductor manufacturing apparatus of claim 1, wherein
the chuck is configured to support a substrate, and
an area of the reflective surface of the reflector is larger than an area of an upper surface of the chuck.

5. The semiconductor manufacturing apparatus of claim 1, further comprising:
a reflector actuator configured to control a location of the reflector or an angle of the reflector.

6. The semiconductor manufacturing apparatus of claim 1, wherein
the beam generator comprises a plurality of grids that is configured to convert the ions into the ion beams.

7. The semiconductor manufacturing apparatus of claim 1, wherein
the reflector comprises a plurality of sub-reflectors.

8. The semiconductor manufacturing apparatus of claim 1, wherein
the ion generator is outside of the first chamber and comprises coils configured to generate a plasma; and
the plasma comprises the ions.

9. The semiconductor manufacturing apparatus of claim 1, wherein
the reflector comprises at least one from among undoped silicon, doped silicon, aluminum, molybdenum, ruthenium, carbon compounds, tantalum nitride (TaN), and titanium nitride (TiN).

10. The semiconductor manufacturing apparatus of claim 9, wherein
the reflector comprises a plurality of stacked layers; and
each of the plurality of stacked layers comprises at least one from among undoped silicon, doped silicon, aluminum, molybdenum, ruthenium, carbon compounds, tantalum nitride (TaN), and titanium nitride (TiN).

11. The semiconductor manufacturing apparatus of claim 1, further comprising a gas supplier that is configured to supply an inert gas to the first internal space,
wherein the ions are inert ions.

12. The semiconductor manufacturing apparatus of claim 11, wherein the gas supplier is configured to supply argon, neon, or xenon, and
the ions are argon ions, neon ions, or xenon ions.

13. A semiconductor manufacturing apparatus comprising:
a first chamber including a first internal space;
an ion generator configured to generate ions within the first internal space;
a second chamber including a second internal space, the second internal space communicatively connected to the first internal space;
a beam generator between the first internal space and the second internal space and configured to convert the ions into ion beams;
a chuck within the second chamber; and
a reflector within the second chamber, the reflector comprising a reflective surface that is curved, and the reflector configured to reflect the ion beams toward the chuck,
wherein the reflective surface of the reflector is configured to reflect the ion beams in a first direction at different angles, the different angles being in a cross-sectional view of the semiconductor manufacturing apparatus taken along a plane that is parallel to the first direction and a second direction that crosses the first direction.

14. The semiconductor manufacturing apparatus of claim 13, further comprising:
an ion neutralizer connected to the reflector and configured to neutralize the ion beams.

15. The semiconductor manufacturing apparatus of claim 13, wherein
the reflector comprises a plurality of sub-reflectors.

16. The semiconductor manufacturing apparatus of claim 13, wherein
the reflector comprises at least one from among undoped silicon, doped silicon, aluminum, molybdenum, ruthenium, carbon compounds, tantalum nitride (TaN), and titanium nitride (TiN).

17. A semiconductor manufacturing apparatus comprising:
a first chamber including a first internal space;
an ion generator configured to generate ions within the first internal space;
a second chamber including a second internal space, the second internal space communicatively connected to the first internal space;
a beam generator between the first internal space and the second internal space and configured to convert the ions into ion beams;
a chuck within the second chamber and configured to support a substrate; and
a reflector within the second chamber, the reflector comprising a plurality of sub-reflectors that comprise a reflective surface that is curved, and the plurality of sub-reflectors configured to reflect the ion beams toward the chuck.

18. The semiconductor manufacturing apparatus of claim 17, further comprising:
at least one ion neutralizer connected to the reflector and configured to neutralize the ion beams.

19. The semiconductor manufacturing apparatus of claim 17, wherein
the plurality of sub-reflectors are arranged with respect to each other in at least two directions that cross each other.

20. The semiconductor manufacturing apparatus of claim 17, wherein
each of the plurality of sub-reflectors comprises a plurality of stacked layers; and
each of the plurality of stacked layers comprises at least one from among undoped silicon, doped silicon, aluminum, molybdenum, ruthenium, carbon compounds, tantalum nitride (TaN), and titanium nitride (TiN).
